(19) United States
(12) Patent Application Publication
(10) Pub. No.: US 2007/0272927 A1
(43) Pub. Date: Nov. 29, 2007

(54) THIN FILM TRANSISTOR, METHOD OF MANUFACTURING THE THIN FILM TRANSISTOR, ACTIVE MATRIX TYPE DISPLAY DEVICE, AND METHOD OF MANUFACTURING THE ACTIVE MATRIX TYPE DISPLAY DEVICE

(75) Inventors: Toru Takeguchi, Tokyo (JP); Kaoru Motonami, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Tokyo (JP)

(21) Appl. No.: 11/695,769

(22) Filed: Apr. 3, 2007

(30) Foreign Application Priority Data
Apr. 20, 2006 (JP) 2006-117237

(51) Int. Cl. H01L 29/04; H01L 21/336; H01L 29/786

(52) U.S. Cl. 257/72; 257/66; 438/166; 257/E29.273; 257/E21.412; 257/E29.003

(57) ABSTRACT

A TFT according to an embodiment of the present invention includes an insulative base film formed on a TFT array substrate, and a semiconductor film including a channel region formed on the base film, in which an impurity concentration of a channel region in the semiconductor film becomes substantially uniform in a film thickness direction of the semiconductor film, the impurity concentration of the channel region is discontinuous at a boundary between the semiconductor film and the base film, and an impurity concentration of the base film is lower than an impurity concentration of the semiconductor film and is monotonously decreased toward the TFT array substrate.

### BACKGROUND OF THE INVENTION

1. Field of the Invention

The present invention relates to a thin film transistor, a method of manufacturing the thin film transistor, an active matrix type display device, and a method of manufacturing the active matrix type display device.

2. Description of Related Art

As an example of typical conventional thin-model panels, there is a liquid crystal display device (LCD). The liquid crystal display device is advantageous in terms of low power consumption, small size, and light weight. Thus, the liquid crystal display device has been widely used for monitor screens of a personal computer, a portable information terminal, and the like. Moreover, in recent years, the liquid crystal display device has been widely used for a TV screen. As described above, a conventional cathode-ray tube has given way to the liquid crystal display device.

Further, as next-generation thin display panel devices, electroluminescence (EL) display devices such as an organic EL display device have been used. In the electroluminescence (EL) display devices, a light emitter such as an EL element is used in a pixel display unit. Therefore, the electroluminescence (EL) display device surpasses the liquid crystal display device in easiness of control over view angle and contrast. In addition, the electroluminescence (EL) display device is suitable for moving pictures because of its high response speed. The electroluminescence (EL) display device is self-luminous and has advantages over the liquid crystal display device in wide view angle, high contrast, and high response speed.

As a drive system for pixels of the liquid crystal display device or organic EL display device, an active matrix drive system based on arrayed thin film transistors (TFTs) has been widely used. In the active matrix type display device, a TFT array substrate having TFTs arrayed thereon is used. In general, TFTs of such active matrix type display device are structured such that a silicon layer formed on a glass substrate has a source region, a drain region, and a channel region.

Most of the TFTs of such display device have MOS structure including a silicon film. TFTs for display devices are classified into an inversely staggered type, a top-gate type, and the like. Regarding the kind of silicon film, there are an amorphous silicon (a-Si) film and a polysilicon (p-Si) film. A desired one is appropriately selected from the films in accordance with application and performance of a display device. As for a small panel, a polysilicon film that would contribute to size reduction of a TFT is used in many cases because an aperture ratio of a display area can be increased.

A method of manufacturing a TFT with a polysilicon film is disclosed (see Japanese Unexamined Patent Application Publication No. 11-163367). According to this method, first, an amorphous silicon film is formed on a silicon oxide film or the like as a base film. Laser light is applied to the amorphous silicon film to thereby polycrystallize the amorphous silicon film.

Then, a gate insulating film made of silicon oxide is formed on the polysilicon film. A gate electrode is formed on the gate insulating film. Then, impurities such as phosphorous and boron are doped to the polysilicon film through the gate electrode and the gate insulating film. As a result, a source/drain region can be formed in the polysilicon film. After that, an interlayer insulating film is formed on the gate electrode and the gate insulating film. A contact hole is formed in the interlayer insulating film and the gate insulating film so as to reach the source/drain region.

Next, a metal film is formed on the interlayer insulating film. The metal film is patterned and connected to the source/drain region. As a result, a source electrode and a drain electrode are formed to thereby complete a TFT. In a display device, the drain electrode is connected with a pixel electrode or a self-luminous element. There has also been known a method of doping boron or other such impurities to a channel region as an activation region through a gate insulating film, for example, to improve TFT characteristics at this time (see Japanese Unexamined Patent Application Publication No. 11-68114).

The manufacturing method as disclosed in Japanese Unexamined Patent Application Publication No. 11-68114 uses ion implantation as a method of injecting boron to a channel region in a silicon film to improve TFT characteristics. Then, boron is injected to the channel region through the gate insulating film. Thus, a profile of a boron concentration of the silicon film in a film thickness direction varies depending on doping conditions or insulating film materials. For example, a concentration profile has a gradient in the film thickness direction and its maximum and minimum points appear at a predetermined depth. For example, as shown in FIG. 8, the maximum point of the impurity concentration appears around the boundary between the gate insulating film and the polysilicon film. If a semiconductor film having such concentration profile is used, the following problems occur.

In a TFT having the above profile, an impurity concentration becomes low at the bottom of the polysilicon film. Therefore, a depletion layer tends to develop at the bottom of the polysilicon film. As a result, a leak current is likely to flow in the TFT and a source-drain breakdown voltage is lowered.

Further, during boron ion implantation, boron ions are undesirably implanted to a gate insulating film overlying the silicon film or a base film underlying the silicon film. Some of the boron ions implanted to the films other than the silicon film function as a fixed charge and influence a threshold voltage of the TFT. For example, in the case where there are boron ions in a gate insulating film, a TFT operates as if a positive voltage were applied to the channel region beforehand. As a result, a threshold voltage seems to lower. If there is the maximum point of a boron concentration profile in the gate insulating film, TFT operations are unstable.

Further, the gate insulating film is generally formed by CVD, so a film thickness varies in some cases. In this case, the number of boron ions in the film also varies on the substrate. Accordingly, a threshold voltage of the TFT varies.

Further, if the base film contains boron ions, some of the boron ions in the base film function as a fixed charge. Thus, a back bias is applied to the channel region all the time. This involves variations in threshold voltage of a TFT as well. As described above, the conventional TFT has a problem of unstable characteristics.

### SUMMARY OF THE INVENTION

The present invention has been accomplished in view of the above circumstances. Accordingly, the present invention aims at providing a thin film transistor having stable characteristics, a method of manufacturing the thin film transistor, an active matrix type display device, and a method of manufacturing the active matrix type display device.

According to a first aspect of the present invention, a thin film transistor includes: an insulative base film formed on a substrate; and a semiconductor film including a channel region formed on the base film, wherein an impurity concentration of the channel region in the semiconductor film is substantially constant in a film thickness direction of the semiconductor film, the impurity concentration of the channel region is discontinuous at a boundary between the semiconductor film and the base film, and an impurity concentration of the base film is lower than an impurity concentration of the semiconductor film and is monotonously decreased toward the substrate.

According to a second aspect of the invention, a method of manufacturing a thin film transistor includes: sequentially forming an insulative base film, an amorphous semiconductor film, and an insulating film on a substrate; injecting an impurity to the semiconductor film through the insulating film formed on the semiconductor film; removing the insulating film on the semiconductor film doped with the impurity to expose the semiconductor film; annealing and polycrystallizing the exposed semiconductor film; forming a gate insulating film on the polycrystallized semiconductor film; and forming a gate electrode on the gate insulating film.

According to the present invention, it is possible to provide a thin film transistor having stable characteristics, a method of manufacturing the thin film transistor, an active matrix type display device, and a method of manufacturing the active matrix type display device.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view of the structure of an active matrix type organic EL display device according to a first embodiment of the present invention;

FIG. 2 is a plan view schematically showing the structure of a TFT of the first embodiment;

FIG. 3 is a sectional view taken along the line III-III of FIG. 2;

FIG. 4 shows an impurity concentration profile of the TFT of the first embodiment;

FIGS. 5A to 5D are sectional views of a manufacturing process of the TFT of the first embodiment in step order;

FIG. 6 shows an impurity concentration profile of a TFT according to a second embodiment of the present invention;

FIG. 7 shows TFT characteristics of the embodiments of the present invention and TFT characteristics of the Related Art; and

FIG. 8 shows an impurity concentration profile of a conventional TFT.

### DESCRIPTION OF THE PREFERRED EMBODIMENTS

Hereinafter, the invention will be described with reference to illustrative embodiments. The following description is made of the embodiments of the present invention. The present invention is not limited to the embodiments.

### First Embodiment

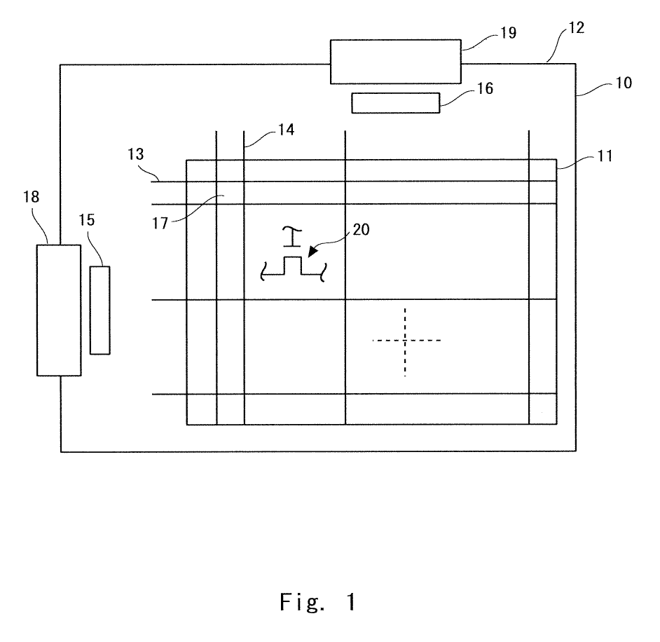

Referring to FIG. 1, an active matrix type display device according to a first embodiment of the present invention is described below. FIG. 1 is a plan view of the structure of the active matrix type display device of this embodiment.

The display device of this embodiment includes a thin film transistor array substrate (hereinafter referred to as “TFT array substrate”) 10. The TFT array substrate 10 includes a display area 11 and a frame region 12 surrounding the display area 11. In the display area 11, plural scanning signal lines 13 and plural display signal lines 14 are formed. The plural scanning signal lines 13 are formed in parallel. Likewise, the plural display signal lines 14 are formed in parallel. The scanning signal line 13 and the display signal line 14 cross each other. The scanning signal line 13 and the display signal line 14 are orthogonal to each other. A region surrounded by the scanning signal line 13 and the display signal line 14 adjacent to each other corresponds to a pixel 17. Accordingly, the pixels 17 are arranged in matrix in the TFT array substrate 10.

Further, in the frame region 12 of the TFT array substrate 10, a scanning signal drive circuit 15 and a display signal drive circuit 16 are formed. The scanning signal line 13 extends from the display area 11 to the frame region 12. Then, the scanning signal line 13 is connected to the scanning signal drive circuit 15 at the edge of the TFT array substrate 10. The display signal line 14 also extends from the display area 11 to the frame region 12. Then, the display signal line 14 is connected to the display signal drive circuit 16 at the edge of the TFT array substrate 10. The external line 18 is connected near the scanning signal drive circuit 15. Further, the external line 19 is connected near the display signal drive circuit 16. The external lines 18 and 19 are constituted by a wiring board such as FPC (Flexible Printed Circuit).

Various signals are externally supplied through the external lines 18 and 19 to the scanning signal drive circuit 15 and the display signal drive circuit 16. In accordance with an external control signal, the scanning signal drive circuit 15 supplies a scanning signal to the scanning signal line 13. In response to the scanning signal, the scanning signal lines 13 are selected one by one. The display signal drive circuit 16 supplies a display signal to the display signal line 14 based on an external control signal or display data. Thus, a display voltage corresponding to the display data is applied to each pixel 17. Incidentally, the scanning signal drive circuit 15 and the display signal drive circuit 16 are not necessarily formed on the TFT array substrate 10. For example, a drive circuit may be connected by use of TCP (Tape Carrier Package).

As for an organic EL display device, a common line (not shown) for applying a common potential or a power supply voltage line (not shown) for applying a power supply voltage are formed aside from the scanning signal line 13 and the display signal line 14. The common line and the power supply voltage line extend from the display area 11 to the frame region 12 similar to the scanning signal line 13 and the display signal line 14. Hence, a common potential and a power supply voltage can be externally applied to the pixel 17.

In the pixel 17, at least one thin film transistor (TFT) 20 is formed. For example, if the TFT 20 is a driving TFT for supplying a driving current to the organic EL element, an organic EL element is connected with a drain of the TFT 20. To be specific, the drain of the TFT 20 is connected with a pixel electrode. Further, a display signal is supplied to a gate of the TFT 20 through a switching TFT (not shown). Further, a power supply voltage is applied to a source of the TFT 20. Then, an opposing electrode is placed opposite to the pixel electrode. An organic light emitting layer is formed between the pixel electrode and the opposing electrode to thereby complete an organic EL element. Further, a common potential is applied to the opposing electrode. In this way, the pixel electrode and the opposing electrode sandwich the organic light emitting layer. Accordingly, the TFT 20 serves as a control element for controlling a driving current that flows through the organic light emitting layer.

If the switching TFT is turned on in response to the scanning signal, a display voltage is applied to the gate of the driving TFT 20 through a switching TFT. Here, a display voltage corresponding to the display data is applied to the display signal line 14. Hence, the driving TFT 20 can supply a driving current corresponding to the display voltage to the organic EL element. In this case, the scanning signal is used to sequentially select the scanning signal lines 13 one by one. Then, only a switching TFT of a pixel connected to the selected scanning signal line 13 is turned on. At the timing when the switching TFT is turned on, a display voltage corresponding to the pixel 17 is applied to the pixel 17 from the display signal line 14. A predetermined driving current corresponding to display data is supplied to each pixel this way. As a result, an organic EL element emits light with luminance corresponding to the display data. Then, in response to the scanning signal, the scanning signal lines 13 are sequentially scanned to thereby display a desired image on the display area 11.

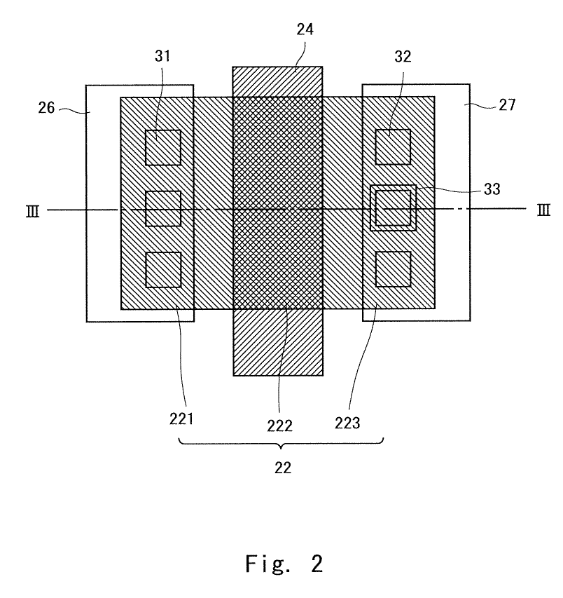

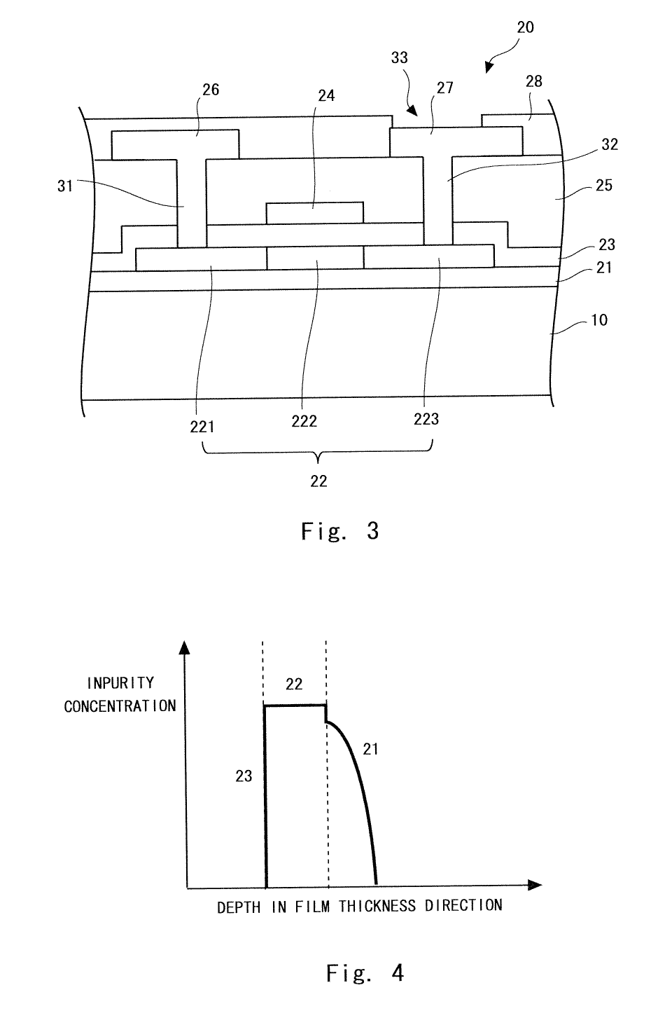

Referring to FIGS. 2 and 3, the structure of the TFT 20 is described next. FIG. 2 is a plan view schematically showing the structure of the TFT 20. FIG. 3 is a sectional view taken along the line III-III of FIG. 2 and schematically shows the structure of the TFT 20. Reference numeral 21 denotes a base film; 22, a semiconductor film; 23, a gate insulating film; 24, a gate electrode; 25, an interlayer insulating film; 26, a source electrode; 27, a drain electrode; 28, a planarizing film; 31, a contact hole; 32, a contact hole; and 33, a contact hole. Here, the TFT 20 is assumed to have a top gate structure where the gate electrode 24 is formed above the semiconductor film 22 made of polysilicon. In the active matrix type display device, the TFT 20 is formed in the pixel 17 in the display area 11.

As the TFT substrate 10, an insulative substrate such as a transparent glass substrate may be used. Alternatively, as the TFT substrate 10, a metal substrate such as an Al- or stainless-steel-made substrate may be used. On the TFT substrate 10, the insulative base film 21 is formed. The base film 21 is formed on substantially the entire surface of the TFT substrate 10. As the base film 21, a silicon nitride film (SiN film) or a silicon oxide film (SiO₂ film) as a light-transmissive insulating film may be used. Needless to say, the base film 21 may be the laminate of these films. The semiconductor film 22 is formed on the base film 21. That is, the base film 21 is formed on the rear side of the semiconductor film 22. Accordingly, the rear surface of the semiconductor film 22 is in contact with the upper surface of the base film 21. The semiconductor film 22 is patterned into an island-like shape. As a result, the semiconductor film 22 on the base film 21 has a rectangular pattern.

The semiconductor film 22 includes a source region 221, a channel region 222, and a drain region 223. The lower surfaces of the source region 221, the channel region 222, and the drain region 223 are adjacent to the base film 21. The channel region 222 is formed between the source region 221 and the drain region 223. The source region 221 and the drain region 223 are conductive regions containing impurities, which face each other across the channel region 222. The channel region 222 specified herein refers to a channel formation region formed at the time of applying a gate voltage to a gate electrode. The semiconductor film 22 is formed of, for example, polycrystalline silicon. Incidentally, upon patterning the semiconductor film 22, the end portions of the semiconductor film 22 may be tapered. As a result, the semiconductor film 22 is completely covered with the gate insulating film 23 as described later. Accordingly, problems about dielectric breakdown and the like can be overcome.

The gate insulating film 23 is formed on the semiconductor film 22. The gate insulating film 23 is formed to cover the entire semiconductor film 22. Accordingly, the lower surface of the gate insulating film 23 is in contact with the upper surface of the semiconductor film 22. Further, the gate electrode 24 is formed on the gate insulating film 23. The gate electrode 24 is positioned above the channel region 222 of the semiconductor film 22. That is, the gate electrode 24 faces the channel region 222 of the semiconductor film 22 across the gate insulating film 23. In this way, the gate electrode 24 faces the channel region 222 of the semiconductor film 22 across the gate insulating film 23. Accordingly, if a gate voltage is applied to the gate electrode 24, a channel region is formed at the surface of the channel region 222. Accordingly, if a gate voltage is applied to the gate electrode 24 while a predetermined voltage is applied between the source region 221 and the drain region 223, a drain current corresponding to the gate voltage flows between the source region 221 and the drain region 223.

Further, the interlayer insulating film 25 is formed on the gate electrode 24 and the gate insulating film 23. The interlayer insulating film 25 is formed to cover the gate electrode 24. A contact hole 31 and a contact hole 32 are formed in the interlayer insulating film 25 and the gate insulating film 23. The contact holes 31 and 32 pass through the interlayer insulating film 25 and the gate insulating film 23. Thus, the contact holes 31 and 32 reach the semiconductor film 22. Here, the contact hole 31 corresponds to the source region 221, and the contact hole 32 corresponds to the drain region 223. That is, the contact hole 31 is formed above the source region 221. The contact hole 32 is formed above the drain region 223.

The source electrode 26 is buried in the contact hole 31. The source electrode 26 filled in the contact hole 31 is connected with the source region 221. A potential is applied to the source region 221 through the source electrode 26. Likewise, the drain electrode 27 is buried in the contact hole 32. The drain electrode 27 filled in the contact hole 32 is connected with the drain region 223. A source-drain voltage of the TFT 20 is applied through the drain electrode 27 and the source electrode 26. Here, as shown in FIG. 2, three contact holes 31 are formed in the source region 221. Likewise, three contact holes 32 are formed in the drain region 223.

As described above, the source electrode 26 and the drain electrode 27 are formed from above the interlayer insulating film 25 to the semiconductor film 22. Accordingly, the source electrode 26 and the drain electrode 27 are exposed from the interlayer insulating film 25. Further, the planarizing film 28 is formed on the interlayer insulating film 25 to cover the source electrode 26 and the drain electrode 27. Incidentally, a contact hole 33 may be formed in the planarizing film 28 and connected to the source electrode 26 and the drain electrode 27.

For example, if the TFT 20 is a driving TFT used for the above organic EL display device, as shown in FIG. 3, the contact hole 33 is formed on the drain electrode 27. The drain electrode 27 is exposed through the contact hole 33 formed in the planarizing film 28. Then, the drain electrode 27 is connected with a pixel electrode (not shown) through the contact hole 33. The pixel electrode is an anode, and the above opposing electrode (not shown) is a cathode. Accordingly, a driving current is supplied to an organic light emitting layer (not shown) formed between the pixel electrode and the opposing electrode through the TFT 20. Hence, the organic light emitting layer emits light. A desired image can be displayed by controlling a driving current for each pixel.

In the TFT 20 of this embodiment, impurities are doped to the semiconductor film 22 made of polysilicon. As the impurities, boron (B) may be used. The impurity concentration is adjusted to thereby control characteristics of the TFT 20 such as a threshold voltage. FIG. 4 shows a profile of the impurity concentration of the semiconductor film 22. In FIG. 4, the horizontal axis represents a depth in a film thickness direction, and the vertical axis represents an impurity concentration. FIG. 4 illustrates a profile of impurity concentration from the gate insulating film 23 just above the channel region 222 to the base film 21 just below the channel region 222. In this embodiment, an impurity concentration in the channel region 222 of the semiconductor film 22 is substantially constant in the film thickness direction. That is, in the channel region 222, the profile of impurity concentration is constant.

The impurity concentration of the channel region 222 is higher than that of the base film 21. That is, a boron ion concentration of the base film 21 is lowered. Further, a break point of the impurity concentration profile appears at the boundary between the semiconductor film 22 and the base film 21. That is, an impurity concentration is abruptly changed at the boundary between the semiconductor film 22 and the base film 21. Further, in the base film 21, the impurity concentration is monotonously decreased. That is, in the base film 21, the impurity concentration is monotonously decreased toward the TFT array substrate 10 side. In other words, the profile of impurity concentration is monotonously decreased toward the TFT array substrate 10 side.

The semiconductor film 22 has the above impurity concentration profile, making it possible to stabilize the characteristics of the TFT 20. For example, in a conventional transistor, an impurity concentration of a polysilicon film shows a gradient in the film thickness direction. Further, a peak point of the impurity concentration of the polysilicon film appears near the boundary between the polysilicon film and the gate insulating film formed on the polysilicon film. Accordingly, an impurity amount is minimum at the bottom of the polysilicon film. Here, in a low-impurity-concentration region, a depletion layer tends to develop. Thus, a conventional thin film transistor has a problem that a leak current is apt to flow at the bottom portion of the polysilicon film, which hardly functions as a channel region. In the TFT 20 of this embodiment, an impurity concentration is constant in the channel region 222 in the film thickness direction. Accordingly, a depletion layer is prevented from developing in the channel region 222. That is, it is possible to prevent formation of a depletion layer at the bottom of the semiconductor film 22. Hence, a leak current can be reduced and a source-drain breakdown voltage can be increased, so desired characteristics can be attained. The above structure prevents the depletion layer from extending in a polysilicon film, and a short-channel effect can be suppressed. Thus, the characteristics of the TFT 20 can be stabilized.

Further, an impurity concentration of the base film 21 is much lower than that of the semiconductor film 22. Thus, a back bias voltage can be lowered and the TFT characteristics can be stabilized. That is, the number of boron ions in the base film 21, which serve as a fixed charge can be reduced. Hence, a back-gate potential can be reduced and the TFT characteristics can be stabilized.

The gate insulating film 23 contains almost no impurities. To be specific, an impurity concentration of the gate insulating film 23 is 5×10¹⁶/cm³ or less. Accordingly, variations in threshold voltage of the TFT 20 can be suppressed. The characteristics of the TFT 20 can be thereby stabilized.

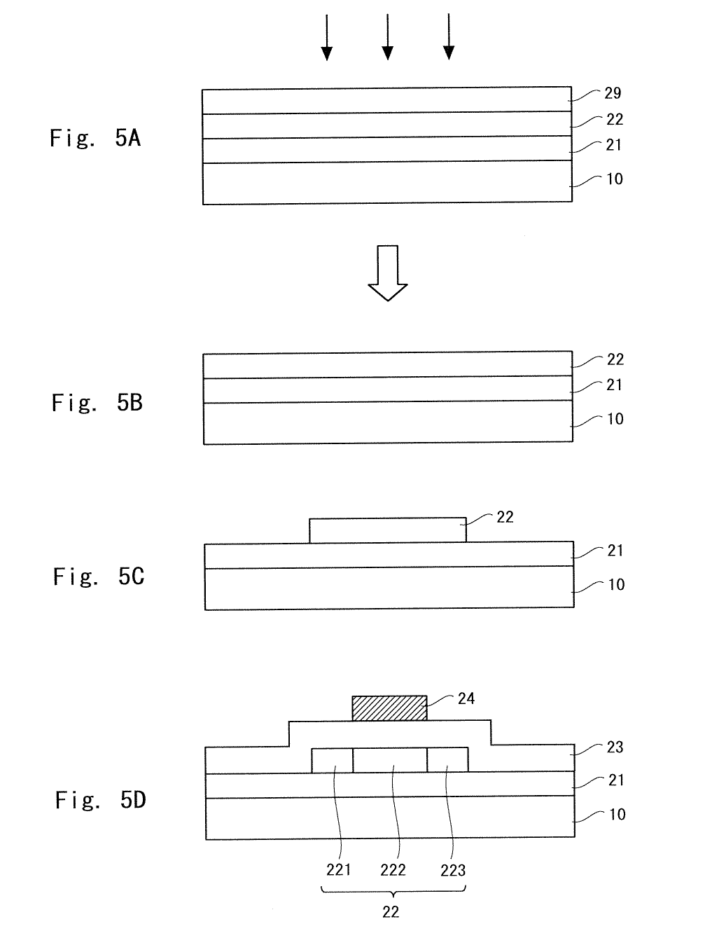

Referring next to FIGS. 5A to 5D, a manufacturing process of the TFT 20 of this embodiment is described below. FIGS. 5A to 5D are sectional views showing the manufacturing process for the TFT 20 in step order. Further, as the TFT array substrate 10, an insulative substrate such as a transparent glass substrate is prepared. Then, the base film 21, the semiconductor film 22, and an impurity-injection insulating film 29 are formed in this order on the TFT array substrate 10. As shown in FIG. 5A, three thin films are thereby formed on the TFT array substrate 10. Here, an SiO₂ film, an amorphous silicon film, and an SiO₂ film are sequentially formed by CVD. Accordingly, the lower SiO₂ film serves as the base film 21, the intermediate amorphous silicon film serves as the semiconductor film 22, and the upper SiO₂ film serves as the impurity-injection insulating film 29. Here, the base film 21 has a film thickness of 200 nm, the semiconductor film 22 has a film thickness of 70 nm, and the impurity-injection insulating film 29 has a film thickness of 80 nm. The base film 21, the semiconductor film 22, and the impurity-injection insulating film 29 are formed on substantially the entire surface of the TFT array substrate 10. Incidentally, the base film 21 may be an SiN film, not the SiO₂ film or may be the laminate of these films. Further, the impurity-injection insulating film 29 may be made of the other materials. Moreover, a conductive film other than the insulating film may be formed on the semiconductor film 22.

Next, impurity ions are implanted through the upper impurity-injection insulating film 29. In this case, boron (B) is doped as an impurity. The doped boron controls a threshold voltage of the TFT 20. At this time, a boron ion accelerating voltage is set such that a peak point of the impurity concentration in the film thickness direction appears near the boundary between the semiconductor film 22 and the impurity-injection insulating film 29. Here, ion implantation is executed under the condition that an implantation energy of the boron ion is 40 KeV. Further, boron ions are implanted such that a peak impurity concentration is 7×10¹⁶/cm³. Under this state, an impurity concentration of the semiconductor film 22 has a gradient in the film thickness direction. That is, an impurity concentration of the semiconductor film 22 is monotonously decreased from the peak point to the base film 21 side. Incidentally, impurities are injected to substantially the entire surface of the semiconductor film 22. In this way, impurities are doped to the semiconductor film 22 through the impurity-injection insulating film 29 in this embodiment. Accordingly, boron ions are decelerated in the impurity-injection insulating film 29. Thus, a peak point of the impurity concentration can be easily controlled to near the boundary between the semiconductor film 22 and the impurity-injection insulating film 29. Incidentally, a peak point of the impurity concentration is not limited to near the boundary but may appear in the impurity-injection insulating film 29. Further, boron is used as an impurity to thereby easily control a threshold voltage.

Next, the impurity-injection insulating film 29 is removed with chemicals or the like. In this example, an SiO₂ film as the impurity-injection insulating film 29 can be removed with BHF (buffered hydrofluoric acid). Thus, almost all of the impurity-injection insulating film 29 on the semiconductor film 22 is removed. Accordingly, the semiconductor film 22 is exposed at substantially the entire surface. In this state, a peak point of the impurity concentration of the semiconductor film 22 appears near the surface.

Next, the exposed semiconductor film 22 is irradiated with laser light and annealed. As a result, the structure of FIG. 5B is obtained. When the laser light is applied, the semiconductor film 22 made of amorphous silicon is polycrystallized. Thus, the semiconductor film 22 may be turned into a polysilicon film. In this case, laser light of an excimer laser with a wavelength of 308 nm is applied from the surface side of the TFT array substrate 10 to the semiconductor film 22. At this time, the laser light is converted into a linear beam profile through a predetermined optical system and then applied to the semiconductor film 22. Incidentally, the excimer laser is used in this embodiment, but a YAG laser may be used. Further, a CW (Continuous-Wave) laser or pulse laser may be used. Here, laser light may be applied to the entire surface of the semiconductor film 22 or applied to a required region alone. That is, laser light may be applied to only the semiconductor film 22 that is not removed after a subsequent patterning step. Further, the present invention is not limited to laser annealing, and thermal annealing may be carried out. In the case where Ni or other such catalysts are used upon thermal annealing, polysilicon of a larger grain size can be obtained.

As described above, the semiconductor film 22 is annealed and the amorphous silicon film is melt. At this time, polycrystallization is carried out, and in addition, impurities are diffused in the semiconductor film 22. That is, impurities are diffused in the semiconductor film 22 from a high-concentration region to a low-concentration region. Thus, in the semiconductor film 22, impurities are diffused from near the surface portion having a high impurity concentration toward the base film side. Then, laser light is applied such that an impurity concentration of the semiconductor film 22 becomes uniform. As a result, an impurity concentration of the semiconductor film 22 in the depth direction can be uniform. That is, impurities in the channel region are uniformly distributed in the film thickness direction. For example, an impurity concentration is 5×10¹⁶/cm³, and an impurity distribution is 15% or less. As a result, the semiconductor film 22 having a uniform impurity concentration in the film thickness direction can be formed. In this case, the laser light irradiation conditions are, for example, a feed pitch of 10 μm and a laser power density of 370 mJ/cm⁻². By heating the semiconductor film 22 with laser light in this way, impurities can be distributed uniformly in the semiconductor film 22.

Incidentally, an Sio₂ film that hardly absorbs laser light is used as the base film 21. Therefore, the base film 21 is not melt. That is, laser light that can be transmitted through the base film 21 is used to thereby prevent the base film 21 from being heated. As a result, an impurity profile of the base film 21 is not changed from a profile just after the impurity injection. That is, an impurity concentration profile of the base film 21 is not changed after annealing the base film 21.

Through the above annealing, an impurity concentration of the semiconductor film 22 is changed, but an impurity concentration of the base film 21 is not changed. Further, impurities are diffused in the semiconductor film 22, and an impurity concentration increases near the bottom of the semiconductor film 22 through annealing. On the other hand, an impurity concentration is lowered near the upper surface of the semiconductor film 22. At this time, the entire quantity of impurities in the semiconductor film 22 is little changed. Regarding an area near the boundary between the semiconductor film 22 and the base film 21, an impurity concentration becomes high on the semiconductor film 22 side after annealing, and an impurity concentration is not changed on the base film 21 side. Accordingly, even if an impurity concentration is continuous near the boundary between the semiconductor film 22 and the base film 21 immediately after the impurity injection, the impurity concentration is not continuous after annealing. That is, even if the impurity concentration profile is gently changed near the boundary before annealing but changed sharply after annealing. As a result, an impurity concentration is not continuous at the boundary between the semiconductor film 22 and the base film 21. Further, in the injection step, a peak boron concentration is set to appear near the boundary. Thus, an impurity concentration is largely changed near the bottom of the semiconductor film 22. That is, a difference in impurity concentration profile near the boundary between the semiconductor film 22 and the base film 21 can be increased through annealing.

Further, in an impurity injection step, a peak impurity concentration is set to appear near the boundary between the semiconductor film 22 and the impurity-injection insulating film 29. Accordingly, an impurity concentration of the base film 21 becomes lower than that of the semiconductor film 22. Further, an impurity concentration of the base film 21 is monotonously decreased in the depth direction. That is, in the base film 21, an impurity concentration profile is monotonously decreased toward the TFT array substrate 10 side. In this way, impurities are doped to the semiconductor film 22 through the impurity-injection insulating film 29. After the injection, the impurity-injection insulating film 29 is removed and then the semiconductor film 22 is annealed. As a result, an impurity distribution in the depth direction can be set to a desired distribution to thereby attain the above effects. Incidentally, an impurity concentration becomes substantially uniform in the source region 221, the channel region 222, and the drain region 223 of the semiconductor film 22.

After annealing, the semiconductor film 22 is processed based on photoengraving. As a result, the semiconductor film 22 is processed into a desired pattern. For example, resist application, exposure, development, etching, and removal of the resist are carried out to pattern the semiconductor film 22. The structure of FIG. 5C is thereby completed. After patterning the semiconductor film 22, the gate insulating film 23 is formed. The gate insulating film 23 is formed by, for example, CVD. It is important to prevent a trap level of electrons or holes at the boundary between the gate insulating film 23 and the semiconductor film 22. A CVD film that less causes a trap level can be made of, for example, a TEOS-based material or can be attained by heat treatment as a wet process after the film formation.

As described above, after the injection step, the impurity-injection insulating film 29 is removed to expose the semiconductor film 22. Impurities are injected to the exposed semiconductor film 22, and then the gate insulating film 23 is formed. Hence, the gate insulating film 23 not containing impurities can be formed. Through the above steps, an impurity concentration of the gate insulating film 23 can be set to 5×10¹⁶/cm³ or less. Accordingly, characteristics of the TFT 20 can be stabilized. That is, in the conventional TFT 20, impurities are doped through the gate insulating film 23, so impurities remain in the gate insulating film 23. In the conventional thin film transistor, impurities remaining in the gate insulating film 23 function as fixed charge to change the threshold voltage. However, in the TFT 20 of this embodiment, the gate insulating film 23 is formed after the impurity injection, and no impurities remain in the gate insulating film 23 just below the gate electrode 24. Hence, a threshold voltage of the TFT 20 can be stabilized.

Then, the gate electrode 24 is formed on the gate insulating film 23. The gate electrode 24 may be made of metal- or impurity-doped polysilicon. For example, aluminum or aluminum alloy is deposited into a film and then, the film is patterned through photoengraving. The gate electrode 24 can be thereby formed on the gate insulating film 23. A pattern of the gate electrode 24 is formed above the channel region 222 of the semiconductor film 22. As a result, the structure of FIG. 5D is obtained to thereby complete the TFT 20.

After that, P (phosphorus) or As (arsenic) is doped to the semiconductor film 22 through the gate electrode 24 and the gate insulating film 23. In this example, the gate electrode 24 serves as a mask, so P ions are not implanted to the channel region 222 but implanted to the source region 221 and the drain region 223. As a result, the source region 221 and the drain region 223 have an n-type conductivity. Incidentally, a dose of phosphorous is set mush higher than that of boron. Hence, the source region 221 and the drain region 223 become conductive regions. Alternatively, P ions may be implanted through a resist layer on the gate electrode 24. That is, after the gate electrode 24 is patterned, P ions may be implanted prior to the removal of the resist. In this case, the gate electrode 24 and the resist layer on the gate electrode 24 serve as a mask upon ion implantation.

Further, as shown in FIG. 3, the interlayer insulating film 25, the source electrode 26, the drain electrode 27, the planarizing film 28, and the like are formed. These can be formed through a general photoengraving process. That is, thin film formation, resist application, exposure, development, etching, and removal of a resist are repeated. Further, materials for the thin films are selected from existing materials in accordance with characteristics of each layer as appropriate. For example, the interlayer insulating film 25 is formed and then the contact holes 31 and 32 are formed. The contact holes 31 and 32 are formed to expose the source region 221 and the drain region 223. Then, Al or Al alloy is deposited into a conductive film on the interlayer insulating film 25. The conductive film is patterned through photoengraving to thereby form the source electrode 26 connected to the source region 221 and the drain electrode 27 connected to the drain region 223. Further, patterns of a pixel electrode, an organic light emitting layer, and an opposing electrode are formed on the planarizing film 28. Moreover, a common line, a power supply voltage line, or the like may be formed although not shown. In this way, the TFT array substrate 10 having the TFTs 20 arranged in matrix is completed.

The TFT array substrate 10 is preferred for the active matrix type display device. As described above, the TFT 20 having stable characteristics is set in the pixel to thereby improve display quality. In particular, the TFT 20 is suitable for the driving TFT used in a current drive display device such as an inorganic EL display device or an organic EL display device. Needless to say, the TFT 20 of this embodiment may be used for a liquid crystal display device. Hence, a display device having high display quality can be provided.

### Second Embodiment

The TFT 20 according to a second embodiment of the present invention differs from that of the first embodiment in impurity concentration of the semiconductor film 22 and the base film 21. The basic structure of the TFT of this embodiment is similar to that of the TFT 20 of the first embodiment, so its description is omitted here. That is, the TFT of this embodiment has the structure as shown in FIGS. 1 and 2, and can be manufactured through the steps described with reference to FIGS. 5A to 5D.

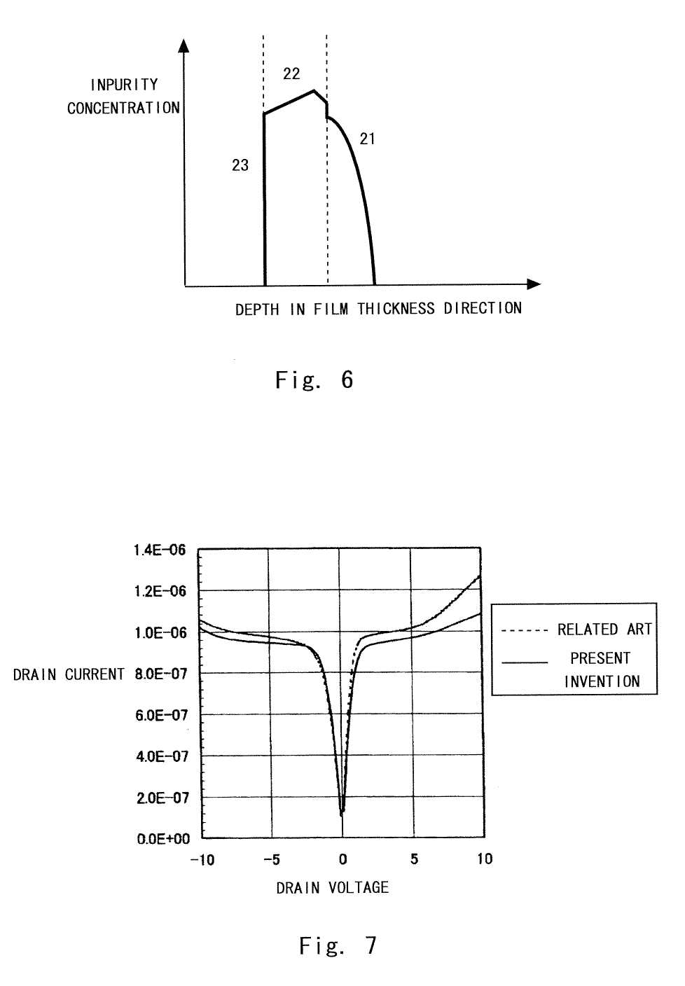

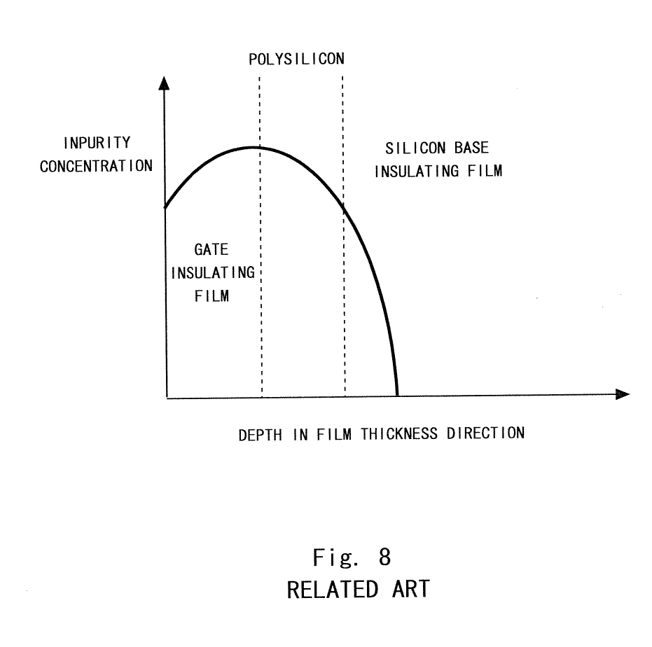

FIG. 6 shows a profile of an impurity concentration of the TFT 20 of this embodiment. The profile of FIG. 6 is an impurity concentration profile in a depth direction. As shown in FIG. 6, a peak point of an impurity concentration of the semiconductor film 22 appears on the base film 21 side. That is, the peak point of the impurity concentration in the film thickness direction appears closer to the base film 21 than the center of the semiconductor film 22. In this way, an impurity concentration is set to have a peak point at the bottom of the semiconductor film 22.

In this embodiment, an implantation energy is set higher than that of the first embodiment to realize the above profile. That is, a boron ion accelerating voltage is set such that a peak point of the impurity concentration appears closer to the bottom of the semiconductor film 22 than the center thereof. For example, the boron ion accelerating voltage can be set to 60 keV. As a result, a peak impurity concentration is obtained 40 nm away from the bottom of the semiconductor film 22. An impurity concentration at the bottom of the semiconductor film 22 can be thereby increased.

After impurities are doped, similar to the first embodiment, an impurity-injection insulating film 29 is removed and annealing is carried out. As a result of annealing, impurities are distributed. Here, in the annealing step, annealing is executed to make an impurity concentration nonuniform. For example, the same annealing conditions as the first embodiment can be used. Hence, a peak point of the impurity concentration is shifted from the center of the semiconductor film 22 in the film thickness direction to the base film 21 side.

As described above, in this embodiment, a peak point of the impurity concentration appears at the bottom of the semiconductor film 22. Accordingly, at the bottom of the semiconductor film 22, a p-type conductivity is obtained, and accumulation of holes just below a channel region 222, which are generated by ionizing collision during normal transistor operations can be suppressed. Thus, a source-drain breakdown voltage can be improved. Moreover, kink characteristics in Id-Vd characteristics can be improved. That is, the increase of drain current is suppressed in a saturation region of the TFT 20. As described above, characteristics of the TFT 20 can be stabilized.

Further, similar to the first embodiment, an impurity concentration of the channel region 222 is higher than that of the base film 21. Moreover, there is a break point of the impurity concentration profile at the boundary between the semiconductor film 22 and the base film 21. That is, at the boundary between the semiconductor film 22 and the base film 21, an impurity concentration is abruptly changed. Further, in the base film 21, the impurity concentration is monotonously decreased. That is, in the base film 21, an impurity concentration is monotonously decreased toward the TFT array substrate 10 side. In other words, an impurity concentration profile is monotonously decreased toward the TFT array substrate 10 side.

Here, similar to the first embodiment, the impurity concentration of the gate insulating film 23 is 5×10¹⁶/cm³ or less. That is, after the boron ion implantation, the gate insulating film 23 is formed to reduce an impurity concentration of the gate insulating film 23. Thus, variations in threshold voltage due to the fixed charge can be suppressed. Accordingly, stable TFT characteristics are attained.

Incidentally, a difference between the TFT characteristics of the present invention and conventional TFT characteristics is described below with reference to FIG. 7. In FIG. 7, the dotted line represents characteristics of a conventional TFT, and the solid line represents characteristics of the TFT of the present invention. The horizontal axis represents a drain voltage (Vd), and the vertical axis represents a drain current (Id). Regarding the conventional TFT characteristics, in IdVd saturation regions, a drain voltage and a drain current increase. That is, in the conventional TFT, kink characteristics are obvious. On the other hand, in the TFT of the present invention, IdVd curve becomes more flat and the leak current is reduced in the IdVd saturation region. As described above, the structures of the first and second embodiments improve TFT characteristics.

### Other Embodiments

Incidentally, the above embodiment dopes impurities through ion implantation, but the present invention is not limited thereto. For example, plasma doping may be carried out. Further, the above TFT 20 is not limited to the organic EL display device, and the present invention is applicable to the other active matrix type display devices such as an inorganic EL display device or a liquid crystal display device.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor, comprising:
an insulative base film formed on a substrate; and
a semiconductor film including a channel region formed on the base film,
wherein an impurity concentration of the channel region in the semiconductor film is substantially constant in a film thickness direction of the semiconductor film,
the impurity concentration of the channel region is discontinuous at a boundary between the semiconductor film and the base film, and
an impurity concentration of the base film is lower than an impurity concentration of the semiconductor film and is monotonously decreased toward the substrate.

2. A thin film transistor, comprising:
an insulative base film formed on a substrate; and
a semiconductor film including a channel region formed on the base film,
wherein a peak point of an impurity concentration of the channel region in the semiconductor film appears closer to the base film than a central portion of the semiconductor film in a film thickness direction,
the impurity concentration of the channel region is discontinuous at a boundary between the semiconductor film and the base film, and
an impurity concentration of the base film is lower than an impurity concentration of the semiconductor film and is monotonously decreased toward the substrate.

3. The thin film transistor according to claim 1, further comprising a gate insulating film formed on the channel region of the semiconductor film,
wherein an impurity concentration of the gate insulating film is 5×10¹⁶/cm³ or less.

4. The thin film transistor according to claim 2, further comprising a gate insulating film formed on the channel region of the semiconductor film,
wherein an impurity concentration of the gate insulating film is 5×10¹⁶/cm³ or less.

5. The thin film transistor according to claim 1, wherein an impurity contained in the base film and the semiconductor film is boron.

6. The thin film transistor according to claim 2, wherein an impurity contained in the base film and the semiconductor film is boron.

7. An active matrix type display device, comprising:
thin film transistors according to claim 1; and
a TFT array substrate having the arrayed thin film transistors.

8. An active matrix type display device, comprising:
thin film transistors according to claim 2; and
a TFT array substrate having the arrayed thin film transistors.

9. A method of manufacturing a thin film transistor, comprising:
sequentially forming an insulative base film, an amorphous semiconductor film, and an insulating film on a substrate;
injecting an impurity to the semiconductor film through the insulating film formed on the semiconductor film;
removing the insulating film on the semiconductor film doped with the impurity to expose the semiconductor film;
annealing and polycrystallizing the exposed semiconductor film;
forming a gate insulating film on the polycrystallized semiconductor film; and
forming a gate electrode on the gate insulating film.

10. The method of manufacturing a thin film transistor according to claim 9, wherein the impurity injection includes injecting the impurity such that a peak concentration of the impurity in the semiconductor film in a film thickness direction appears near a boundary between the semiconductor film and the insulating film.

11. The method of manufacturing a thin film transistor according to claim 10, wherein the polycrystallization includes annealing in such a manner that an impurity concentration of a channel region in the semiconductor film becomes substantially uniform in a film thickness direction.

12. The method of manufacturing a thin film transistor according to claim 9, wherein the impurity injection includes injecting the impurity such that a peak point of an impurity concentration of the channel region in the semiconductor film appears closer to the base film than a central portion of the semiconductor film in a film thickness direction.

13. The method of manufacturing a thin film transistor according to claim 9, wherein the polycrystallization includes applying laser light to the semiconductor film to execute annealing.

14. A method of manufacturing an active matrix type display device, comprising:
arraying thin film transistors with a method of manufacturing a thin film transistor according to claim 9.
